(19) United States
(12) Patent Application Publication
(10) Pub. No.: US 2023/0005964 A1
(43) Pub. Date: Jan. 5, 2023

(54) DISPLAY DEVICE

(71) Applicant: Samsung Display Co., LTD., Yongin-si (KR)

(72) Inventors: Yongduck SON, Seongnam-si (KR); Jeong Hwan KIM, Hwaseong-si (KR); Taehui KIM, Asan-si (KR); Junhwi PARK, Asan-si (KR); Dabin LEE, Seoul (KR); Yujin LEE, Cheonan-si (KR); Wonho JANG, Hwaseong-si (KR)

(73) Assignee: Samsung Display Co., LTD., Yongin-si (KR)

(21) Appl. No.: 17/856,493

(22) Filed: Jul. 1, 2022

(30) Foreign Application Priority Data
Jul. 2, 2021 (KR) 10-2021-0086924

(51) Int. Cl. H01L 27/12

(52) U.S. Cl. CPC H01L 27/124; H01L 27/1225; H01L 27/1274

(57) ABSTRACT

A display device includes a first light blocking layer disposed on a substrate, a second light blocking layer disposed on the substrate and spaced apart from the first light blocking layer, an active layer including a first area disposed on the first light blocking layer, a second area disposed on the substrate between the first light blocking layer and the second light blocking layer, and a third area disposed between the first area and the second area, a gate electrode disposed on the active layer and overlapping a portion of the first area, a first electrode disposed on the gate electrode, and including at least a portion overlapping the first light blocking layer, and a second electrode disposed on the gate electrode, and including at least a portion overlapping the second light blocking layer and at least another portion overlapping the third area of the active layer.

### CROSS-REFERENCE TO RELATED APPLICATION(S)

This application claims priority to and the benefit of Korean Patent Application No. 10-2021-0086924 under 35 USC § 119, filed in the Korean Intellectual Property Office (KIPO) on Jul. 2, 2021, the entire content of which is incorporated herein by reference.

### BACKGROUND

### 1. Technical Field

The disclosure relates to a display device including a semiconductor element.

### 2. Description of the Related Art

A display device includes multiple pixels. Each of the pixels may include at least one transistor including a semiconductor element. The semiconductor element may include an active layer, a gate electrode, first and second electrodes being in contact with the active layer, and an insulating material.

The active layer may be made of oxide semiconductor. The oxide semiconductor may be susceptible to impurities. For example, the oxide semiconductor may be eroded or disconnected by the impurities. In this case, characteristic of the display device may be deteriorated.

### SUMMARY

Embodiments of the disclosure provide a display device having increased characteristic.

However, embodiments of the disclosure are not restricted to those set forth herein. The above and other embodiments of the disclosure will become more apparent to one of ordinary skill in the art to which the disclosure pertains by referencing the detailed description of the disclosure given below.

According to an embodiment of the disclosure, a display device may include a first light blocking layer disposed on a substrate, a second light blocking layer disposed on the substrate and spaced apart from the first light blocking layer in a first direction, an active layer including a first area disposed on the first light blocking layer, a second area disposed on the substrate between the first light blocking layer and the second light blocking layer, and a third area disposed between the first area and the second area, a gate electrode disposed on the active layer and overlapping at least a portion of the first area, a first electrode disposed on the gate electrode and including at least a portion overlapping the first light blocking layer, and a second electrode disposed on the gate electrode and including at least a portion overlapping the second light blocking layer and at least another portion overlapping the third area of the active layer.

In an embodiment, the active layer may include a step overlapping a boundary of the first light blocking layer in the third area.

In an embodiment, the display device may further include a first insulating layer disposed between the first light blocking layer and the active layer and overlapping the first light blocking layer and the second light blocking layer, a gate insulating layer disposed between the active layer and the gate electrode, and a second insulating layer disposed between the gate electrode and the first electrode and overlapping the gate electrode, the gate insulating layer, and the active layer.

In an embodiment, the first electrode may contact the first area through a first through hole that penetrates the second insulating layer and exposes an upper surface of the first area, the second electrode may contact the second area through a second through hole that penetrates the second insulating layer and exposes an upper surface of the second area, and the second electrode may contact the second light blocking layer through a third through hole that penetrates the first insulating layer and the second insulating layer and exposes an upper surface of the second light blocking layer.

In an embodiment, the active layer may include an oxide semiconductor.

In an embodiment, the oxide semiconductor may include indium gallium zinc oxide.

In an embodiment, the first light blocking layer may include a protruding portion protruding in the first direction, and the second light blocking layer may include an indenting portion indenting in the first direction corresponding to the protruding portion.

In an embodiment, at least a portion of the first area may be disposed on the protruding portion.

In an embodiment, the first area may further include a first extension area adjacent to the third area and extending in the first direction, a second extension area adjacent to the first extension area and extending in a second direction perpendicular to the first direction, and an overlapping area adjacent to the second extension area and including at least a portion overlapping the gate electrode.

In an embodiment, the first area may further include a first extension area adjacent to the third area and extending in a second direction perpendicular to the first direction, a second extension area adjacent to the first extension area and extending in the first direction, a third extension area adjacent to the second extension area, spaced apart from the first extension area in a direction opposite to the first direction, and extending in the second direction, a fourth extension area adjacent to the third extension area and extending in the first direction, and an overlapping area adjacent to the fourth extension area and including at least a portion overlapping the gate electrode.

A display device according to an embodiment may include a first light blocking layer disposed on a substrate and including a through hole, a second light blocking layer disposed on the substrate and spaced apart from the first light blocking layer in a first direction, an active layer disposed on the first light blocking layer and including a first area overlapping the through hole and a second area adjacent to the first area, a gate electrode disposed on the active layer and overlapping at least a portion of the second area, a first electrode disposed on the gate electrode and including at least a portion overlapping the first light blocking layer, and a second electrode disposed on the gate electrode and including at least a portion overlapping the second light blocking layer and at least another portion overlapping the through hole.

In an embodiment, the active layer may include a step overlapping a boundary between the substrate and the through hole in the first area.

In an embodiment, the display device may further include a first insulating layer disposed between the first light blocking layer and the active layer and overlapping the first light blocking layer and the second light blocking layer, a gate insulating layer disposed between the active layer and the gate electrode, and a second insulating layer disposed between the gate electrode and the first electrode and overlapping the gate electrode, the gate insulating layer, and the active layer.

In an embodiment, the first electrode may contact the second area through a first through hole that penetrates the second insulating layer and exposes an upper surface of the second area, the second electrode may contact the first area through a second through hole that penetrates the second insulating layer, exposes an upper surface of the first area, and overlaps the through hole, and the second electrode may contact the second light blocking layer through a third through hole that penetrates the first insulating layer and the second insulating layer and exposes an upper surface of the second light blocking layer.

In an embodiment, the active layer may include an oxide semiconductor.

In an embodiment, the oxide semiconductor may include indium gallium zinc oxide.

In an embodiment, the first light blocking layer may include a protruding portion protruding in the first direction, and the second light blocking layer may include an indenting portion indenting in the first direction corresponding to the protruding portion.

In an embodiment, the through hole may overlap the protruding portion in plan view.

In an embodiment, the second area may further include a first extension area adjacent to the first area and extending in the first direction, a second extension area adjacent to the first extension area and extending in a second direction perpendicular to the first direction, and an overlapping area adjacent to the second extension area and including at least a portion overlapping the gate electrode.

In an embodiment, the second area may further include a first extension area adjacent to the first area and extending in a second direction perpendicular to the first direction, a second extension area adjacent to the first extension area and extending in the first direction, a third extension area adjacent to the second extension area, spaced apart from the first extension area in a direction opposite to the first direction, and extending in the second direction, a fourth extension area adjacent to the third extension area and extending in the first direction, and an overlapping area adjacent to the fourth extension area and including at least a portion overlapping the gate electrode.

The second electrode of the display device according to the embodiments of the disclosure may overlap the step of the active layer. Accordingly, the second electrode may protect the step of the active layer from impurities.

### BRIEF DESCRIPTION OF THE DRAWINGS

Illustrative, non-limiting embodiments will be more clearly understood from the following detailed description taken in conjunction with the accompanying drawings.

FIG. 1 is a schematic plan view illustrating a display device according to an embodiment.

FIGS. 2 to 7 are schematic diagrams illustrating an embodiment of a pixel included in the display device of FIG. 1.

FIGS. 8 to 13 are schematic diagrams illustrating another embodiment of a pixel included in the display device of FIG. 1.

### DETAILED DESCRIPTION OF THE EMBODIMENTS

Reference will now be made in detail to embodiments, with the accompanying drawings wherein like reference numerals refer to like elements throughout. In this regard, the embodiments may have different forms and should not be construed as being limited to the descriptions set forth herein. Accordingly, the embodiments are merely described below, by referring to the figures, to explain aspects of the disclosure. As used herein, the term “and/or” includes any and all combinations of one or more of the associated listed items. Throughout the disclosure, the expression “at least one of a, b, or c” or “at least one of a, b, or c” indicates only a, only b, only c, both a and b, both a and c, both b and c, all of a, b, and c, or variations thereof.

As the disclosure allows for various changes and numerous embodiments will be illustrated in the drawings and described in the detailed description. Effects and features of the disclosure, and methods for achieving the same will be apparent with reference to embodiments described below in detail with the accompanying drawings. However, the disclosure is not limited to the following embodiments disclosed below and may be implemented in various forms.

Reference will now be made in detail to embodiments, examples of which are illustrated in the accompanying drawings, and in the drawings, the same elements are denoted by the same reference numerals, and thus a repeated description thereof will be omitted.

Although the terms “first,” “second,” and the like may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be further understood that the terms “comprises” or “comprising” used herein specify the presence of stated features or components, but do not preclude the presence or addition of one or more other features or components.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or contracted for convenience of explanation. For example, because sizes and thicknesses of elements in the drawings are arbitrarily illustrated for convenience of explanation, the disclosure is not limited thereto.

When an embodiment may be implemented differently, a specific process order may be different from the described order. For example, two consecutively described processes may be performed substantially at the same time or may be performed in an order opposite to the described order.

It will be understood that when a layer, region, or component is referred to as being “connected,” the layer, the region, or the component may be directly connected or may be indirectly connected with intervening layers, regions, or components therebetween. For example, when layers, regions, or components are referred to as being “electrically connected,” the layers, the regions, or the components may be directly electrically connected, or may be indirectly electrically connected with intervening layers, regions, or components therebetween.

Further, in the specification, the phrase “in a plan view” means when an object portion is viewed from above, and the phrase “in a schematic cross-sectional view” means when a cross-section taken by vertically cutting an object portion is viewed from the side. Additionally, the terms “overlap” or “overlapped” mean that a first object may be above or below or to a side of a second object, and vice versa. Additionally, the term “overlap” may include layer, stack, face or facing, extending over, covering or partly covering or any other suitable term as would be appreciated and understood by those of ordinary skill in the art. The terms “face” and “facing” mean that a first object may directly or indirectly oppose a second object. In a case in which a third object intervenes between the first and second object, the first and second objects may be understood as being indirectly opposed to one another, although still facing each other.

When a layer, region, substrate, or area, is referred to as being “on” another layer, region, substrate, or area, it may be directly on the other film, region, substrate, or area, or intervening regions, substrates, or areas, may be present therebetween. Conversely, when a layer, region, substrate, or area, is referred to as being “directly on” another layer, region, substrate, or area, intervening layers, regions, substrates, or areas, may be absent therebetween. Further when a layer, region, substrate, or area, is referred to as being “below” another layer, region, substrate, or area, it may be directly below the other layer, region, substrate, or area, or intervening layers, regions, substrates, or areas, may be present therebetween. Conversely, when a layer, region, substrate, or area, is referred to as being “directly below” another layer, region, substrate, or area, intervening layers, regions, substrates, or areas, may be absent therebetween. Further, “over” or “on” may include positioning on or below an object and does not necessarily imply a direction based upon gravity.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

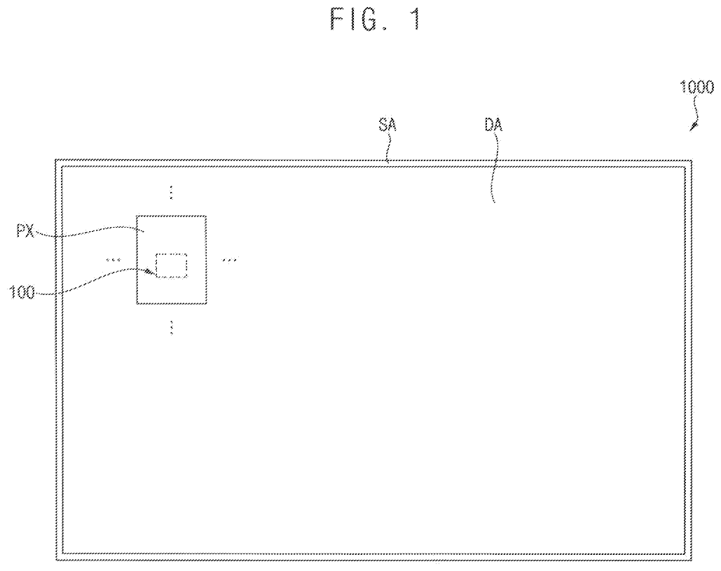

FIG. 1 is a schematic plan view illustrating a display device according to an embodiment.

Referring to FIG. 1, a display device 1000 may include a display area DA and a peripheral area SA.

The display area DA may be an area displaying an image. A pixel PX may be disposed in the display area DA. The pixel PX may be arranged in a matrix form. The pixel PX may receive an electrical signal and may emit light having a luminance corresponding to an intensity of the electrical signal.

The peripheral area SA may surround the display area DA. A driving circuit for driving the pixel PX may be disposed in the peripheral area SA. For example, the driving circuit may generate the electrical signal and provide the electrical signal to the pixel PX. In an embodiment, the peripheral area SA may be omitted. In this case, the driving circuit may be disposed in the display area DA.

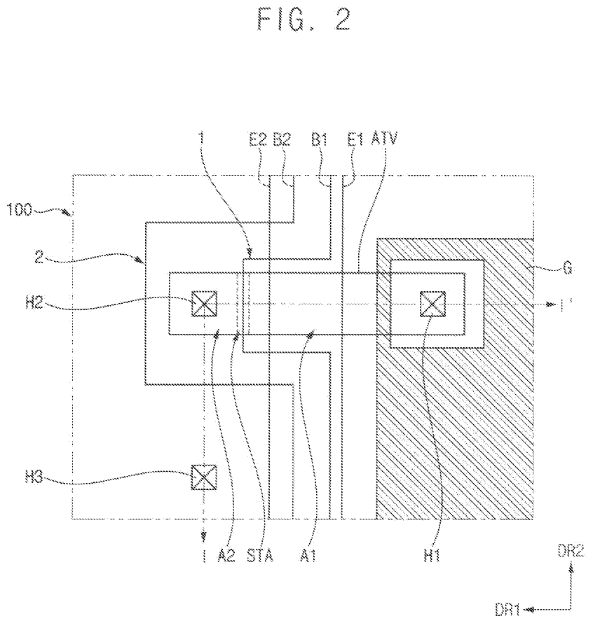

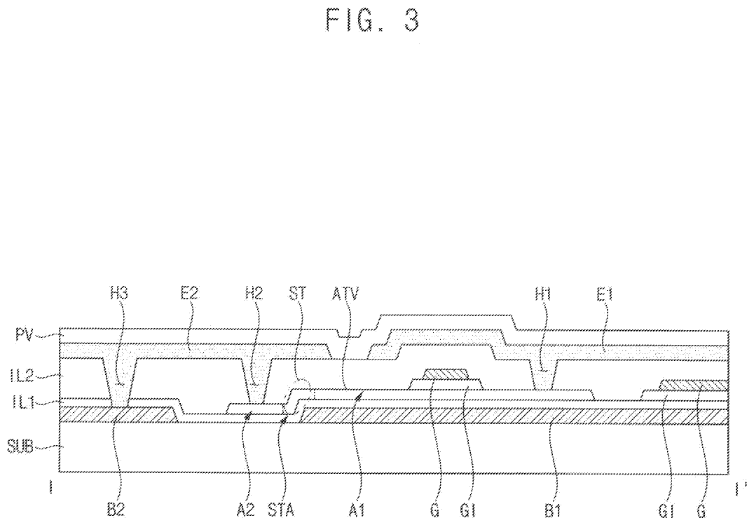

FIG. 2 and FIG. 3 are schematic diagrams illustrating an embodiment of a pixel PX included in the display device of FIG. 1. FIG. 2 is a schematic plan view enlarging a partial area 100 of the pixel PX of FIG. 1. FIG. 3 is a cross-sectional view taken along a line of FIG. 2.

Referring to FIG. 2 and FIG. 3, the pixel PX may include a substrate SUB, a first light blocking layer B1, a second light blocking layer B2, an active layer ATV, a gate electrode G, a first electrode E1, a second electrode E2, a passivation layer PV, a first insulating layer ILL a second insulating layer IL2, and a gate insulating layer GI.

The substrate SUB may include a glass substrate, a quartz substrate, etc. In an embodiment, the substrate may include a plastic substrate, and thus the display device 1000 may have a flexible characteristic.

The first light blocking layer B1 and the second light blocking layer B2 may be disposed on the substrate SUB. The second light blocking layer B2 may be spaced apart from the first light blocking layer B1 in a first direction DR1. The first light blocking layer B1 and the second light blocking layer B2 may block light.

The first light blocking layer B1 and the second light blocking B2 may include a conductive material. For example, the first light blocking layer B1 and the second light blocking B2 may include a metal, an alloy, a conductive metal oxide, etc. For example, the first light blocking layer B1 and the second light blocking B2 may include silver, alloy containing silver, molybdenum, alloy containing molybdenum, aluminum, alloy containing aluminum, aluminum nitride, tungsten, tungsten nitride, copper, nickel, chromium, chromium nitride, titanium, tantalum, platinum, scandium, indium tin oxide, indium zinc oxide, etc.

The active layer ATV may be disposed on the first light blocking layer B1. The active layer ATV may include a semiconductor element. For example, the active layer ATV may include an oxide semiconductor. For example, the oxide semiconductor may include a metal oxide, and the metal oxide may include at least one selected from a group consisting of In—Sn—Ga—Zn—O based oxide semiconductor, In—Ga—Zn—O based oxide semiconductor, In—Sn—Zn—O based oxide semiconductor, In—Al—Zn—O based oxide semiconductor, Sn—Ga—Zn—O based oxide semiconductor, Al—Ga—Zn—O based oxide semiconductor, Sn—Al—Zn—O based oxide semiconductor, In—Zn—O based oxide semiconductor, Sn—Zn—O based oxide semiconductor, Al—Zn—O based oxide semiconductor, Zn—Mg—O based oxide semiconductor, Sn—Mg—O based oxide semiconductor, In—Mg—O based oxide semiconductor, In—Ga—O based oxide semiconductor, In—O based oxide semiconductor, Sn—O based oxide semiconductor, Zn—O based oxide semiconductor, etc.

The active layer ATV may extend to a portion of the substrate SUB that is between the first light blocking layer B1 and the second light blocking layer B2. For example, the active layer ATV may include a first area A1 disposed on the first light blocking layer B1, a second area A2 disposed on the substrate SUB that is between the first light blocking layer B1 and the second light blocking layer B2, and a third area STA disposed between the first area A1 and the second area A2.

In an embodiment, the active layer ATV may have a step ST in the third area STA. The step ST may overlap a boundary of the first light blocking layer B1. In other words, the active area ATV may have an inclined surface in the third area STA overlapping the boundary of the first light blocking layer B1. When the active layer ATV includes an oxide semiconductor, the step ST of the active layer ATV may be vulnerable to damage due to impurities.

In an embodiment, the first light blocking layer B1 may include a protruding portion 1 protruding in the first direction DR1. The second light blocking layer B2 may include an indenting portion 2 indenting in the first direction DR1 corresponding to the protruding portion 1. At least a portion of the first area A1 may be disposed on the protruding portion 1.

In an embodiment, the first insulating layer IL1 may be disposed between the first light blocking layer B1 and the active layer ATV. The first insulating layer IL1 may overlap or cover the first light blocking layer B1 and the second light blocking layer B2. The first insulating layer IL1 may prevent impurities from diffusing into the active layer ATV from the substrate SUB, the first light blocking layer B1, and the second light blocking layer B2. The first insulating layer IL1 may increase a uniformity of the active layer ATV by controlling a heat supply rate during a crystallization process for forming the active layer ATV. The first insulating layer IL1 may include an inorganic insulating material. For example, the inorganic insulating material may include a silicon oxide, a silicon nitride, a titanium oxide, a tantalum oxide, etc.

The gate electrode G may be disposed on the active layer ATV. The gate electrode G may overlap a portion of the first area A1. The gate electrode G may include a conductive material. For example, the gate electrode may include a metal, an alloy, a conductive metal oxide, etc. The gate electrode G may receive an electrical signal to adjust electrical conductivity of the active layer ATV. For example, when the gate electrode G receives the electrical signal greater than or equal to a predetermined voltage, the active layer ATV may have electrical conductivity.

In an embodiment, the gate insulating layer GI may be disposed between the active layer ATV and the gate electrode G. The gate insulating layer GI may insulate the active layer ATV from the gate electrode G. The gate insulating layer GI may include an inorganic insulating material. In an embodiment, the gate insulating layer GI may be formed by chemical vapor deposition (CVD).

The first electrode E1 may be disposed on the gate electrode G. At least a portion of the first electrode E1 may overlap the first light blocking layer B1. The second electrode E2 may be disposed on the gate electrode G. At least a portion of the second electrode E2 may overlap the second light blocking layer B2. At least another portion of the second electrode E2 may overlap the third area STA. The first electrode E1 and the second electrode E2 may include a conductive material having electrical conductivity. Preferably, the first electrode E1 and the second electrode E2 may include copper.

In an embodiment, the second insulating layer IL2 may be disposed between the gate electrode G and the first electrode E1. The second insulating layer IL2 may overlap or cover the gate electrode G, the gate insulating layer GI, and the active layer ATV. The second insulating layer IL2 may insulate the first electrode E1 and the second electrode E2 from the gate electrode G. The second insulating layer IL2 may include an inorganic insulating material.

In an embodiment, the second insulating layer IL2 may include multiple insulating layers. Each of the insulating layers may include an inorganic insulating material. For example, the second insulating layer IL2 may include a first inorganic insulating layer, a second inorganic insulating layer disposed on the first inorganic insulating layer, and a third inorganic insulating layer disposed on the second inorganic insulating layer.

In an embodiment, the passivation layer PV may be disposed on the first electrode E1 and the second electrode E2. The passivation layer PV may overlap or cover the first electrode E1 and the second electrode E2. The passivation layer PV may prevent external oxygen or moisture from contacting the first electrode E1 and the second electrode E2. For example, the passivation layer PV may prevent oxidation of the first electrode E1 and the second electrode E2. The passivation layer PV may include an inorganic insulating material.

In an embodiment, the first electrode E1 may contact the first area A1 through a first through hole H1 that penetrates the second insulating layer IL2 and expose an upper surface of the first area A1. The second electrode E2 may contact the second area A2 through a second through hole H2 that penetrates the second insulating layer IL2 and exposes an upper surface of the second area A2. The second electrode E2 may contact the second light blocking layer B2 through a third through hole H3 that penetrates the first insulating layer IL1 and the second insulating layer IL2 and exposes an upper surface of the second light blocking layer B2.

The second through hole H2 may expose the upper surface of the second area A2. For example, the second through hole H2 may overlap the second area A2 in a plan view and may not overlap the first blocking layer B1. Accordingly, even if the second through hole H2 is overetched, a short may not occur between the second electrode E2 and the first light blocking layer B1.

The second electrode E2 may overlap the third area STA. For example, the second electrode E2 may overlap the step ST of the active layer ATV. A crack may occur in the second insulating layer IL2 overlapping the step ST. Impurities introduced through the crack may contact the third area STA. Accordingly, since the second electrode E2 overlaps the step ST, the second electrode E2 may cover the crack and prevent the impurities from flowing into the step area STA through the crack.

In an embodiment, the first electrode E1 and the second electrode E2 may be formed by patterning a conductive layer including a conductive material having electrical conductivity. As a method of patterning the conductive layer, a wet etching method may be used. For example, when the conductive layer includes copper, the first electrode E1 and the second electrode E2 may be formed by spraying an etchant on the conductive layer to pattern the conductive layer. The second electrode E2 may overlap the third area STA, and accordingly, the second electrode E2 may protect the third area STA from the etchant.

In an embodiment, hydrogen gas may be introduced into the pixel PX through the passivation layer PV. When the hydrogen gas contacts the first electrode E1 and the second electrode E2, the first electrode E1 and the second electrode E2 may not be oxidized, but when the hydrogen gas contacts the active layer ATV, the active layer ATV may be damaged. The second electrode E2 may overlap the third area STA, and accordingly, the second electrode E2 may protect the third area STA from the hydrogen gas.

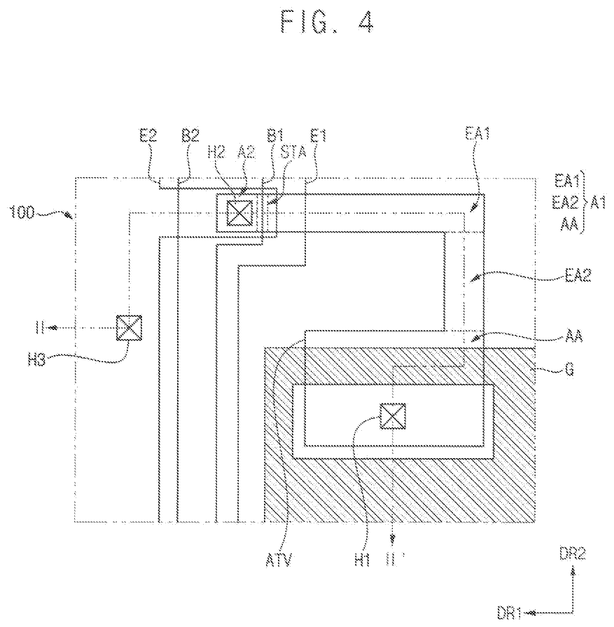

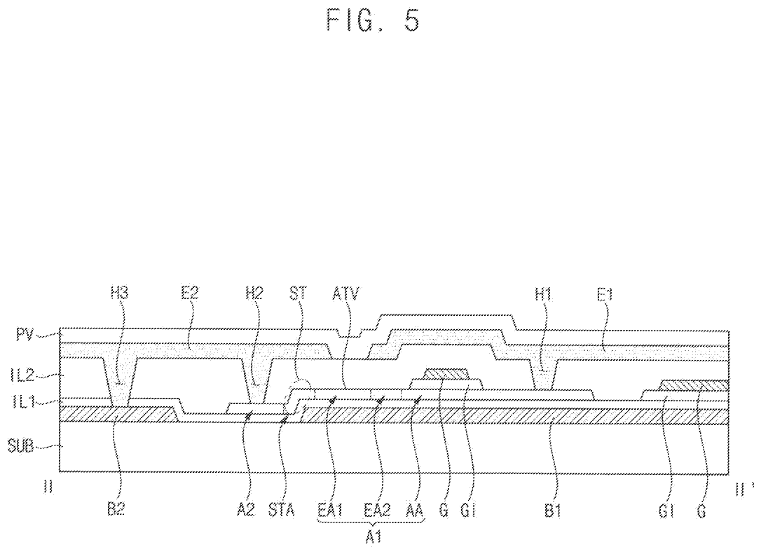

FIG. 4 and FIG. 5 are schematic diagrams illustrating an embodiment of a pixel PX included in the display device 1000 of FIG. 1. FIG. 4 is a schematic plan view enlarging a partial area 100 of the pixel PX of FIG. 1. FIG. 5 is a schematic cross-sectional view taken along a line II-IF of FIG. 4. A description of a configuration overlapping the configuration described with reference to FIG. 2 and FIG. 3 may be omitted.

Referring to FIG. 4 and FIG. 5, the active layer ATV may extend to a portion of the substrate SUB that is between the first light blocking layer B1 and the second light blocking layer B2. For example, the active layer ATV may include a first area A1 disposed on the first light blocking layer B1, a second area A2 disposed on the substrate SUB that is between the first light blocking layer B1 and the second light blocking layer B2, and a third area STA disposed between the first area A1 and the second area A2.

In an embodiment, the active layer ATV may have a step ST in the third area STA. The step ST may overlap a boundary of the first light blocking layer B1.

The first area A1 may include a first extension area EA1, a second extension area EA2, and an overlapping area AA.

The first extension area EA1 may be adjacent to the third area STA. The first extension area EA1 may extend in the first direction DR1. The first extension area EA1 may not overlap the gate electrode G.

The second extension area EA2 may be adjacent to the first extension area EA1. The second extension area EA2 may extend in a second direction DR2 perpendicular to the first direction DR1. The second extension area EA2 may not overlap the gate electrode G.

The overlapping area AA may be adjacent to the second extension area EA2. At least a portion of the overlapping area AA may overlap the gate electrode G. An area overlapping the gate electrode G in the overlapping area AA may define a channel area of a transistor. A first through hole H1 may expose an upper surface of the overlapping area AA, and the first electrode E1 may contact the overlapping area through the first through hole H1.

The first extension area EA1 and the second extension area EA2 may increase a distance from the third area STA to the channel area. Accordingly, even if impurities are introduced into the third area STA, the impurities may be prevented from diffusing to the channel area.

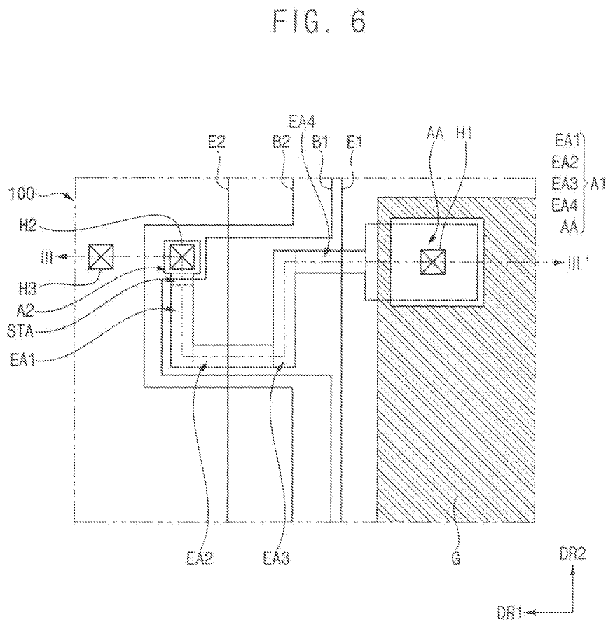

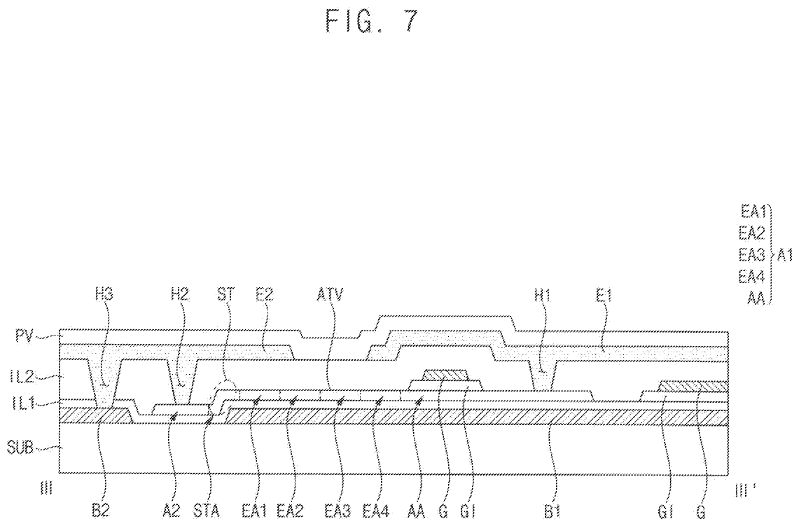

FIG. 6, and FIG. 7 are schematic diagrams illustrating an embodiment of a pixel PX included in the display device 1000 of FIG. 1. FIG. 6 is a schematic plan view enlarging a partial area 100 of the pixel PX of FIG. 1. FIG. 7 is a schematic cross-sectional view taken along a line of FIG. 6. A description of a configuration overlapping the configuration described with reference to FIG. 2 and FIG. 3 may be omitted.

Referring to FIG. 6 and FIG. 7, the active layer ATV may extend to the substrate SUB that is between the first light blocking layer B1 and the second light blocking layer B2. For example, the active layer ATV may include a first area A1 disposed on the first light blocking layer B1, a second area A2 disposed on the substrate SUB that is between the first light blocking layer B1 and the second light blocking layer B2, and a third area STA disposed between the first area A1 and the second area A2.

In an embodiment, the active layer ATV may have a step ST in the third area STA. The step ST may overlap a boundary of the first light blocking layer B1.

The first area A1 may include a first extension area EA1, a second extension area EA2, a third extension area EA3, a fourth extension area EA4, and an overlapping area AA.

The first extension area EA1 may be adjacent to the third area STA. The first extension area EA1 may extend in the second direction DR2. The first extension area EA1 may not overlap the gate electrode G.

The second extension area EA2 may be adjacent to the first extension area EA1. The second extension area EA2 may extend in the first direction DR1. The second extension area EA2 may not overlap the gate electrode G.

The third extension area EA3 may be adjacent to the second extension area EA2. The third extension area EA3 may extend in the second direction DR2. The third extension area EA3 may be spaced apart from the first extension area EA1 in a direction opposite to the first direction DR1. The third extension area EA3 may not overlap the gate electrode G.

The fourth extension area EA4 may be adjacent to the third extension area EA3. The fourth extension area EA4 may extend in the first direction DR1. The fourth extension area EA4 may not overlap the gate electrode G.

The overlapping area AA may be adjacent to the fourth extension area EA4. At least a portion of the overlapping area AA may overlap the gate electrode G. An area overlapping the gate electrode G in the overlapping area AA may define a channel area of a transistor. A first through hole H1 may expose an upper surface of the overlapping area AA, and the first electrode E1 may contact the overlapping area AA through the first through hole H1.

The first extension area EA1, the second extension area EA2, the third extension area EA3, and the fourth extension area EA4 may increase a distance from the third area STA to the channel area. Accordingly, even if impurities are introduced into the third area STA, the impurities may be prevented from diffusing to the channel.

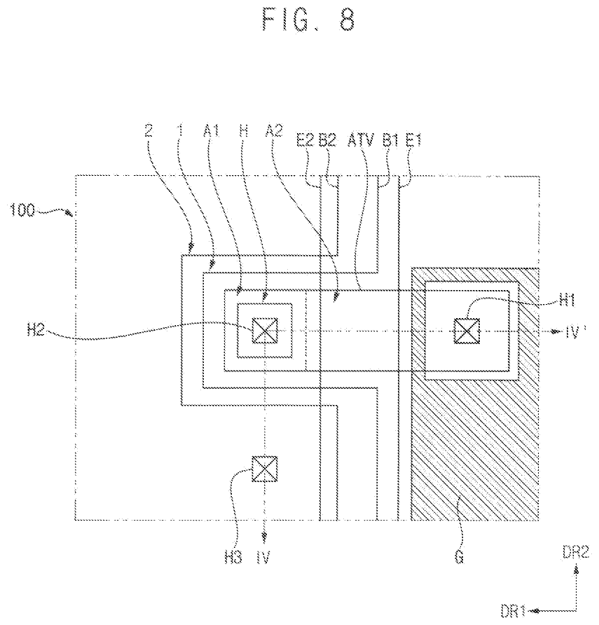

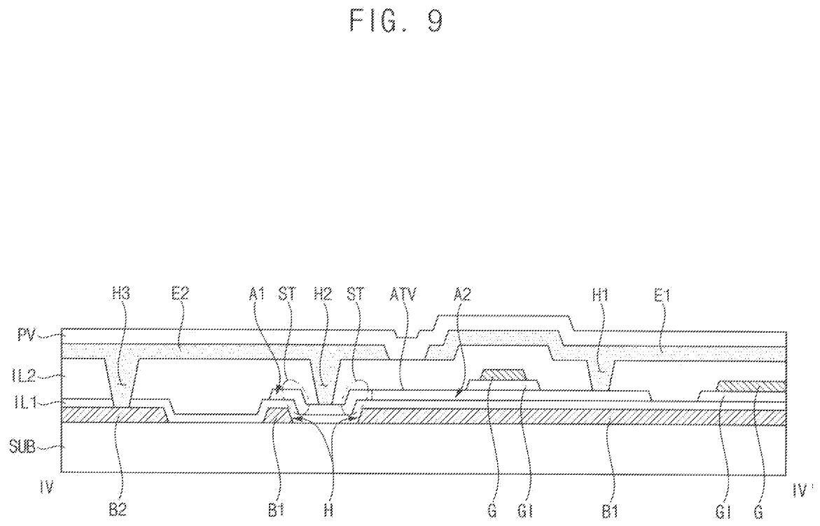

FIG. 8 and FIG. 9 are schematic diagrams illustrating an embodiment of a pixel PX included in the display device 1000 of FIG. 1. FIG. 8 is a schematic plan view enlarging a partial area 100 of the pixel PX of FIG. 1. FIG. 9 is a schematic cross-sectional view taken along a line IV-IV′ of FIG. 8.

Referring to FIG. 8 and FIG. 9, the pixel PX may include a substrate SUB, a first light blocking layer B1, a second light blocking layer B2, an active layer ATV, a gate electrode G, a first electrode E1, a second electrode E2, a passivation layer PV, a first insulating layer ILL a second insulating layer IL2, and a gate insulating layer GI.

The substrate SUB may include a glass substrate, a quartz substrate, etc. In an embodiment, the substrate SUB may include a plastic substrate, and thus, the display device 1000 may have a flexible characteristic.

The first light blocking layer B1 and the second light blocking layer B2 may be disposed on the substrate SUB. The second light blocking layer B2 may be spaced apart from the first light blocking layer B1 in the first direction DR1. The first light blocking layer B1 may have a through hole H. In an embodiment, the through hole H may expose an upper surface of the substrate SUB.

The first light blocking layer B1 and the second light blocking layer B2 may include a conductive material. For example, the first light blocking layer B1 and the second light blocking B2 may include a metal, an alloy, a conductive metal oxide, etc. For example, the first light blocking layer B1 and the second light blocking B2 may include silver, alloy containing silver, molybdenum, alloy containing molybdenum, aluminum, alloy containing aluminum, aluminum nitride, tungsten, tungsten nitride, copper, nickel, chromium, chromium nitride, titanium, tantalum, platinum, scandium, indium tin oxide, indium zinc oxide, etc.

The active layer ATV may be disposed on the first light blocking layer B1. The active layer ATV may include a semiconductor element. For example, the active layer ATV may include an oxide semiconductor. For example, the oxide semiconductor may include a metal oxide, and the metal oxide may include at least one selected from a group consisting of In—Sn—Ga—Zn—O based oxide semiconductor, In—Ga—Zn—O based oxide semiconductor, In—Sn—Zn—O based oxide semiconductor, In—Al—Zn—O based oxide semiconductor, Sn—Ga—Zn—O based oxide semiconductor, Al—Ga—Zn—O based oxide semiconductor, Sn—Al—Zn—O based oxide semiconductor, In—Zn—O based oxide semiconductor, Sn—Zn—O based oxide semiconductor, Al—Zn—O based oxide semiconductor, Zn—Mg—O based oxide semiconductor, Sn—Mg—O based oxide semiconductor, In—Mg—O based oxide semiconductor, In—Ga—O based oxide semiconductor, In—O based oxide semiconductor, Sn—O based oxide semiconductor, Zn—O based oxide semiconductor, etc.

The active layer ATV may include a first area A1 overlapping the through hole H and a second area A2 adjacent to the first area A1. In an embodiment, the active layer ATV may have a step ST in the first area A1. The step ST may overlap a boundary of the through hole H. In other words, the active area ATV may have an inclined surface in the first area A1 overlapping the boundary of the through hole H. When the active layer ATV includes an oxide semiconductor, the step ST of the active layer ATV may be vulnerable to damage due to impurities.

In an embodiment, the first light blocking layer B1 may include a protruding portion 1 protruding in the first direction DR1. The second light blocking layer B2 may include an indenting portion 2 indenting in the first direction DR1 corresponding to the protruding portion 1. In this case, the through hole H may overlap the protruding portion 1.

In an embodiment, the first insulating layer IL1 may be disposed between the first light blocking layer B1 and the active layer ATV. The first insulating layer IL1 may overlap or cover the first light blocking layer B1 and the second light blocking layer B2. The first insulating layer IL1 may prevent impurities from diffusing into the active layer ATV from the substrate SUB, the first light blocking layer B1, and the second light blocking layer B2. The first insulating layer IL1 may increase a uniformity of the active layer ATV by controlling a heat supply rate during a crystallization process for forming the active layer ATV. The first insulating layer IL1 may include an inorganic insulating material. For example, the inorganic insulating material may include a silicon oxide, a silicon nitride, a titanium oxide, a tantalum oxide, etc.

The gate electrode G may be disposed on the active layer ATV. The gate electrode G may overlap a portion of the second area A2. The gate electrode G may include a conductive material. For example, the gate electrode G may include a metal, an alloy, a conductive metal oxide. The gate electrode G may receive an electrical signal to adjust a conductivity of the active layer ATV. For example, when the gate electrode G receives the electrical signal greater than or equal to a predetermined voltage, the active layer ATV may have electrical conductivity.

In an embodiment, the gate insulating layer GI may be disposed between the active layer ATV and the gate electrode G. The gate insulating layer GI may insulate the active layer ATV from the gate electrode G. The gate insulating layer GI may include an inorganic insulating material. In an embodiment, the gate insulating layer GI may be formed by chemical vapor deposition (CVD).

The first electrode E1 may be disposed on the gate electrode G. At least a portion of the first electrode E1 may overlap the first light blocking layer B1. The second electrode E2 may be disposed on the gate electrode G. At least a portion of the second electrode E2 may overlap the first light blocking layer B1. At least another portion of the second electrode E2 may overlap the first area A1. The first electrode E1 and the second electrode E2 may include a conductive material having electrical conductivity. Preferably, the first electrode E1 and the second electrode E2 may include copper.

In an embodiment, the second insulating layer IL2 may be disposed between the gate electrode G and the first electrode E1. The second insulating layer IL2 may overlap or cover the gate electrode G, the gate insulating layer GI, and the active layer ATV. The second insulating layer IL2 may insulate the first electrode E1 and the second electrode E2 from the gate electrode G. The second insulating layer IL2 may include an inorganic insulating material.

In an embodiment, the second insulating layer IL2 may include multiple insulating layers. Each of the insulating layers may include an inorganic insulating material. For example, the second insulating layer IL2 may include a first inorganic insulating layer, a second inorganic insulating layer disposed on the first inorganic insulating layer, and a third inorganic insulating layer disposed on the second inorganic insulating layer.

In an embodiment, the passivation layer PV may be disposed on the first electrode E1 and the second electrode E2. The passivation layer PV may overlap or cover the first electrode E1 and the second electrode E2. The passivation layer PV may prevent external oxygen or moisture from contacting the first electrode E1 and the second electrode E2. For example, the passivation layer PV may prevent oxidation of the first electrode E1 and the second electrode E2. The passivation layer PV may include an inorganic insulating material.

In an embodiment, the first electrode E1 may contact the second area A2 through a first through hole H1 that penetrates the second insulating layer IL2 and exposes an upper surface of the second area A2. The second electrode E2 may contact the first area A1 through a second through hole H2 that penetrates the second insulating layer IL2 and exposes an upper surface of the first area A1. The second electrode E2 may contact the second light blocking layer B2 through a third through hole H3 that penetrates the first insulating layer IL1 and the second insulating layer IL2 and exposes an upper surface of the second light blocking layer B2. The second through hole H2 may overlap the through hole H.

The second through hole H2 may expose an upper surface of the first area A1 that overlaps the through hole H. For example, the second through hole H2 may overlap the first area A1 in a plan view and may not overlap the first light blocking layer B1. Accordingly, even if the second through hole H2 is overetched, a short may not occur between the second electrode E2 and the first light blocking layer B1.

A crack may occur in a portion of the second insulating layer IL2 which overlaps the step ST. Impurities may introduced through the crack and may contact the first area A1. In an embodiment, the second electrode E2 may overlap the through hole H. For example, the second electrode E2 may overlap the step ST of the active layer ATV. Accordingly, since the second electrode E2 overlaps the step ST, the second electrode E2 may cover the crack and prevent the impurities from flowing into the first area A1 through the crack.

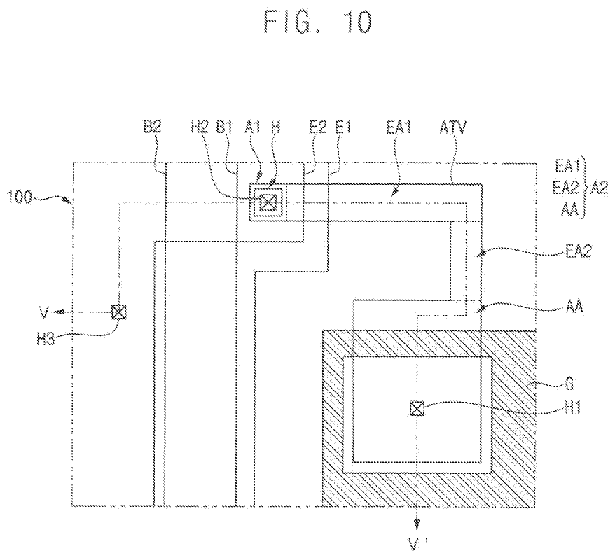

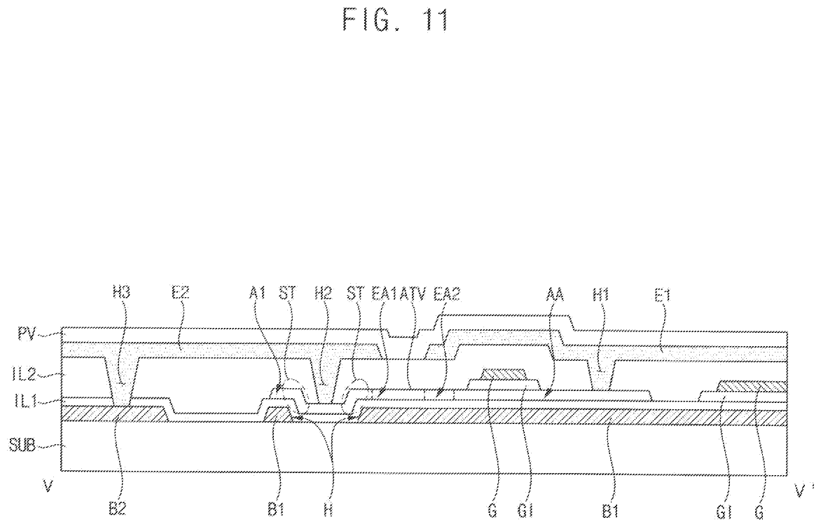

FIG. 10 and FIG. 11 are schematic diagrams illustrating an embodiment of a pixel PX introduced in the display device 1000 of FIG. 1. FIG. 10 is a schematic plan view enlarging a partial area 100 of the pixel PX of FIG. 1. FIG. 11 is a schematic cross-sectional view taken along a line V-V′. A description of a configuration overlapping the configuration described with reference to FIG. 8 and FIG. 9 may be omitted.

Referring to FIG. 10 and FIG. 11, the active layer ATV may include a first area A1 overlapping the through hole H and a second area A2 adjacent to the first area A1. In an embodiment, the active layer ATV may have a step ST in the first area A1. The step ST may overlap the boundary between the through hole H and the substrate SUB.

The second area A2 may include a first extension area EA1, a second extension area EA2, and an overlapping area AA.

The first extension area EA1 may be adjacent to the first area A1. The first extension area EA1 may extend in the first direction DR1. The first extension area EA1 may not overlap the gate electrode G.

The second extension area EA2 may be adjacent to the first extension area EA1. The second extension area EA2 may extend in the second direction DR2. The second extension area EA2 may not overlap the gate electrode G.

The overlapping area AA may be adjacent to the second extension area EA2. At least a portion of the overlapping area AA may overlap the gate electrode G. An area overlapping the gate electrode G in the overlapping area AA may define a channel area of a transistor. The first through hole H1 may expose an upper surface of the overlapping area AA, and the first electrode E1 may contact the overlapping area AA through the first through hole H1.

The first extension area EA1 and the second extension area EA2 may increase a distance from the first area A1 to the channel area. Accordingly, even if impurities are introduced into the step ST, the impurities may be prevented from diffusing to the channel area.

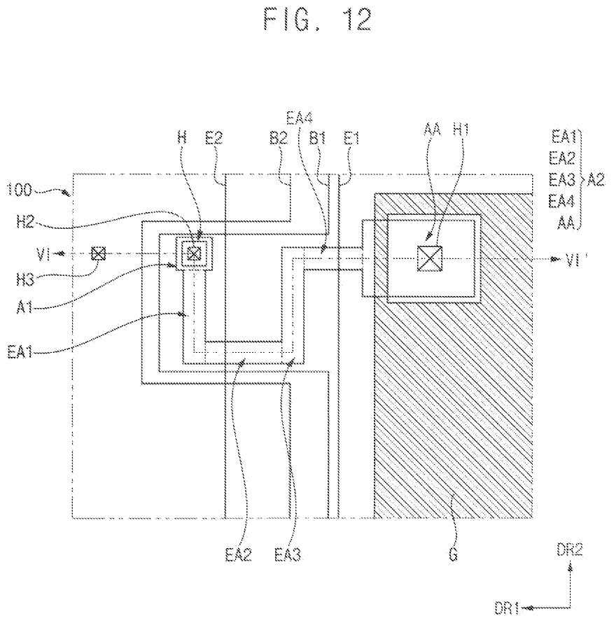

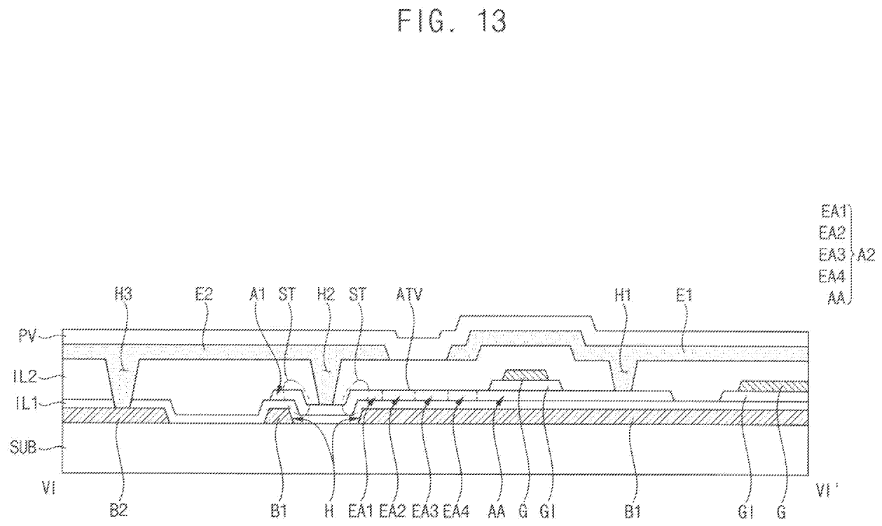

FIG. 12, and FIG. 13 are schematic diagrams illustrating an embodiment of a pixel PX included in the display device 1000 of FIG. 1.

Referring to FIG. 12 and FIG. 13, the active layer ATV may include a first area A1 overlapping the through hole H and a second area A2 adjacent to the first area A1. In an embodiment, the active layer ATV may have a step ST in the first area A1. The step ST may overlap a boundary of the through hole H.

The second area A2 may include a first extension area EA1, a second extension area EA2, a third extension area EA3, a fourth extension area EA4, and an overlapping area AA.

The first extension area EA1 may be adjacent to the first area A1. The first extension area EA1 may extend in the second direction DR2. The first extension area EA1 may not overlap the gate electrode G.

The second extension area EA2 may be adjacent to the first extension area EA1. The second extension area EA2 may extend in the first direction DR1. The second extension area EA2 may not overlap the gate electrode G.

The third extension area EA3 may be adjacent to the second extension area EA2. The third extension area EA3 may extend in the second direction DR2. The third extension area EA3 may be spaced apart from the first extension area EA1 in a direction opposite to the first direction DR1. The third extension area EA3 may not overlap the gate electrode G.

The fourth extension area EA4 may be adjacent to the third extension area EA3. The fourth extension area EA4 may extend in the first direction DR1. The fourth extension area EA4 may not overlap the gate electrode G.

The overlapping area AA may be adjacent to the fourth extension area EA4. At least a portion of the overlapping area AA may overlap the gate electrode G. An area overlapping the gate electrode G in the overlapping area AA may define a channel area of a transistor. A first through hole H1 may expose an upper surface of the overlapping area AA, and the first electrode E1 may contact the overlapping area AA through the first through hole H1.

The first extension area EA1, the second extension area EA2, the third extension area EA3, and the fourth extension area EA4 may increase a distance from the first area A1 to the channel area. Accordingly, even if impurities are introduced into the step ST, the impurities may be prevented from diffusing to the channel area.

Although the display substrate and the display devices according to the embodiments have been described with reference to the drawings, the illustrated embodiments are examples, and may be modified and changed by a person with ordinary knowledge in the relevant technical field without departing from the technical spirit described in the following claims.

What is claimed is:

1. A display device, comprising:
a first light blocking layer disposed on a substrate;
a second light blocking layer disposed on the substrate and spaced apart from the first light blocking layer in a first direction;
an active layer comprising:
a first area disposed on the first light blocking layer;
a second area disposed on the substrate between the first light blocking layer and the second light blocking layer; and
a third area disposed between the first area and the second area;
a gate electrode disposed on the active layer and overlapping at least a portion of the first area;
a first electrode disposed on the gate electrode and including at least a portion overlapping the first light blocking layer; and
a second electrode disposed on the gate electrode and including:
at least a portion overlapping the second light blocking layer; and
at least another portion overlapping the third area of the active layer.

2. The display device of claim 1, wherein the active layer includes a step overlapping a boundary of the first light blocking layer in the third area.

3. The display device of claim 1, further comprising:
a first insulating layer disposed between the first light blocking layer and the active layer and overlapping the first light blocking layer and the second light blocking layer;
a gate insulating layer disposed between the active layer and the gate electrode; and
a second insulating layer disposed between the gate electrode and the first electrode and overlapping the gate electrode, the gate insulating layer, and the active layer.

4. The display device of claim 3, wherein
the first electrode contacts the first area through a first through hole that penetrates the second insulating layer and exposes an upper surface of the first area,
the second electrode contacts the second area through a second through hole that penetrates the second insulating layer and exposes an upper surface of the second area, and
the second electrode contacts the second light blocking layer through a third through hole that penetrates the first insulating layer and the second insulating layer and exposes an upper surface of the second light blocking layer.

5. The display device of claim 1, wherein the active layer comprises an oxide semiconductor.

6. The display device of claim 5, wherein the oxide semiconductor comprises indium gallium zinc oxide.

7. The display device of claim 1, wherein
the first light blocking layer comprises a protruding portion protruding in the first direction, and
the second light blocking layer comprises an indenting portion indenting in the first direction corresponding to the protruding portion.

8. The display device of claim 7, wherein at least a portion of the first area is disposed on the protruding portion.

9. The display device of claim 1, wherein the first area further comprises:
a first extension area adjacent to the third area and extending in the first direction;
a second extension area adjacent to the first extension area and extending in a second direction perpendicular to the first direction; and
an overlapping area adjacent to the second extension area and including at least a portion overlapping the gate electrode.

10. The display device of claim 1, wherein the first area further comprises:
a first extension area adjacent to the third area and extending in a second direction perpendicular to the first direction;
a second extension area adjacent to the first extension area and extending in the first direction;
a third extension area adjacent to the second extension area, spaced apart from the first extension area in a direction opposite to the first direction, and extending in the second direction;
a fourth extension area adjacent to the third extension area and extending in the first direction; and
an overlapping area adjacent to the fourth extension area and including at least a portion overlapping the gate electrode.

11. A display device, comprising:
a first light blocking layer disposed on a substrate and including a through hole;
a second light blocking layer disposed on the substrate and spaced apart from the first light blocking layer in a first direction;
an active layer disposed on the first light blocking layer and comprising:
a first area overlapping the through hole; and
a second area adjacent to the first area;
a gate electrode disposed on the active layer and overlapping at least a portion of the second area;
a first electrode disposed on the gate electrode and including at least a portion overlapping the first light blocking layer; and
a second electrode disposed on the gate electrode and including:
at least a portion overlapping the second light blocking layer; and
at least another portion overlapping the through hole.

12. The display device of claim 11, wherein the active layer includes a step overlapping a boundary between the substrate and the through hole in the first area.

13. The display device of claim 11, further comprising:
a first insulating layer disposed between the first light blocking layer and the active layer and overlapping the first light blocking layer and the second light blocking layer;
a gate insulating layer disposed between the active layer and the gate electrode; and
a second insulating layer disposed between the gate electrode and the first electrode and overlapping the gate electrode, the gate insulating layer, and the active layer.

14. The display device of claim 13, wherein
the first electrode contacts the second area through a first through hole that penetrates the second insulating layer and exposes an upper surface of the second area,
the second electrode contacts the first area through a second through hole that penetrates the second insulating layer, exposes an upper surface of the first area, and overlaps the through hole, and
the second electrode contacts the second light blocking layer through a third through hole that penetrates the first insulating layer and the second insulating layer and exposes an upper surface of the second light blocking layer.

15. The display device of claim 11, wherein the active layer comprises an oxide semiconductor.

16. The display device of claim 15, wherein the oxide semiconductor comprises indium gallium zinc oxide.

17. The display device of claim 11, wherein
the first light blocking layer comprises a protruding portion protruding in the first direction, and
the second light blocking layer comprises an indenting portion indenting in the first direction corresponding to the protruding portion.

18. The display device of claim 17, wherein the through hole overlaps the protruding portion.

19. The display device of claim 11, wherein the second area further comprises:
a first extension area adjacent to the first area and extending in the first direction;
a second extension area adjacent to the first extension area and extending in a second direction perpendicular to the first direction; and
an overlapping area adjacent to the second extension area and including at least a portion overlapping the gate electrode.

20. The display device of claim 11, wherein the second area further comprises:
a first extension area adjacent to the first area and extending in a second direction perpendicular to the first direction;
a second extension area adjacent to the first extension area and extending in the first direction;
a third extension area adjacent to the second extension area, spaced apart from the first extension area in a direction opposite to the first direction, and extending in the second direction;
a fourth extension area adjacent to the third extension area and extending in the first direction; and
an overlapping area adjacent to the fourth extension area and including at least a portion overlapping the gate electrode.
